(19) United States
(12) Patent Application Publication
(10) Pub. No.: US 2024/0429267 A1
(43) Pub. Date: Dec. 26, 2024

(54) CAPACITOR AND SEMICONDUCTOR DEVICE INCLUDING THE SAME

(71) Applicant: Samsung Electronics Co., Ltd., Suwon-si (KR)

(72) Inventors: Jeongil BANG, Suwon-si (KR); Haeryong KIM, Suwon-si (KR); Jaeho LEE, Suwon-si (KR); Jooho LEE, Suwon-si (KR)

(73) Assignee: Samsung Electronics Co., Ltd., Suwon-si (KR)

(21) Appl. No.: 18/515,009

(22) Filed: Nov. 20, 2023

(30) Foreign Application Priority Data
Jun. 20, 2023 (KR) 10-2023-0079144

(51) Int. Cl. H01G 4/008; H10B 12/00

(52) U.S. Cl. CPC H01L 28/60; H01G 4/008; H10B 12/31; H01G 4/1209; H01G 4/1218; H01L 28/56

(57) ABSTRACT

A capacitor includes a first electrode including a conductive layer, a second electrode spaced apart from the first electrode, a dielectric layer disposed between the first electrode and the second electrode, and an interfacial layer disposed between the first electrode and the dielectric layer, wherein the conductive layer includes a first element, a second element, and a third element, the first element includes Ti or Al, the second element includes Ti, Al, Hf, Zr, Ta, Cr, Y, Sc, Si, Nb, Mo, V, W, Mn, Ni, or Co, the third element includes N, the first element and the second element are different from each other, and the conductive layer has a rock salt crystal structure.

### CROSS-REFERENCE TO RELATED APPLICATION

This application is based on and claims priority under 35 U.S.C. § 119 to Korean Patent Application No. 10-2023-0079144, filed on Jun. 20, 2023, in the Korean Intellectual Property Office, the disclosure of which is incorporated by reference herein in its entirety.

### BACKGROUND

### 1. Field

The disclosure relates to a capacitor and a semiconductor device including the same.

### 2. Description of the Related Art

As electronic devices undergo down-scaling, the space occupied by electronic parts within electronic devices is also being reduced. Accordingly, a reduction in the size of an electronic part such as a capacitor and a reduction in the thickness of a dielectric layer of the capacitor are simultaneously required. However, it is difficult to implement a structure that satisfies a reference value of a leakage current while having a thickness of a dielectric layer suitable for a desired capacitance. Thus, a solution has been continuously sought in this regard.

### SUMMARY

Provided is a capacitor having a low leakage current density and suppressing a dielectric permittivity reduction.

Provided is a semiconductor device including a capacitor having a low leakage current density and suppressing a dielectric permittivity reduction.

Additional aspects will be set forth in part in the description which follows and, in part, will be apparent from the description, or may be learned by practice of the presented embodiments of the disclosure.

According to an aspect of the disclosure, a capacitor includes a first electrode including a conductive layer, a second electrode spaced apart from the first electrode, a dielectric layer electrically separating the first electrode and the second electrode, and an interfacial layer between the first electrode and the dielectric layer, wherein the conductive layer comprises a material including a first element, a second element, and a third element, the first element includes Ti or Al, the second element includes at least one of Ti, Al, Hf, Zr, Ta, Cr, Y, Sc, Si, Nb, Mo, V, W, Mn, Ni, or Co, the third element includes N, the first element and the second element are different from each other, and the conductive layer has a rock salt crystal structure.

The conductive layer may include Al, and a composition ratio of the Al may be 63 at % or less.

The interfacial layer may include an oxide of the material included in the conductive layer.

The dielectric layer may include an oxide having a perovskite-type crystal structure.

The dielectric layer may include at least one of Sr, Ba, Ti, Hf, Y or O.

A thickness of the conductive layer may be within a range of 10 Å to about 100 Å.

A thickness of the interfacial layer may be within a range of about 5 Å to about 20 Å.

A thickness of the dielectric layer may be within a range of about 10 Å to about 100 Å.

The conductive layer may be a first conductive layer, and the first electrode may further include a second conductive layer including TiN.

A thickness of the second conductive layer may be within a range of 30 Å to about 500 Å.

The second electrode may include a same material as the conductive layer.

The interfacial layer may be a first interfacial layer, and the capacitor may further include a second interfacial layer disposed between the second electrode and the dielectric layer.

The second interfacial layer may include an oxide of a material constituting the second electrode.

According to another aspect of the disclosure, a semiconductor device includes a transistor including a semiconductor substrate including a source region, a drain region, and a channel region between the source region and the drain region and a gate stack over the channel region, and a capacitor electrically connected to the transistor, wherein the capacitor includes a first electrode including a conductive layer, a second electrode spaced apart from the first electrode, a dielectric layer electrically separating the first electrode and the second electrode, and an interfacial layer between the first electrode and the dielectric layer, the conductive layer comprises a material including a first element, a second element, and a third element, the first element includes Ti or Al, the second element includes at least one of Ti, Al, Hf, Zr, Ta, Cr, Y, Sc, Si, Nb, Mo, V, W, Mn, Ni, or Co, the third element includes N, the first element and the second element are different from each other, and the conductive layer has a rock salt crystal structure.

The conductive layer may include Al, and a composition ratio of the Al may be 63 at % or less.

The interfacial layer may include an oxide of the material included in the conductive layer.

The dielectric layer may include an oxide having a perovskite-type crystal structure.

The dielectric layer may include at least one of Sr, Ba, Ti, Hf, Y or O.

The conductive layer may be a first conductive layer, and the first electrode further may include a second conductive layer including TiN.

The second electrode may include a same material as the material included in the conductive layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a capacitor according to at least one embodiment;

FIG. 2 is a cross-sectional view of a capacitor according to at least one embodiment;

FIGS. 3A to 3C are cross-sectional views illustrating capacitors according to comparative examples;

FIGS. 4 and 5 are graphs illustrating a dielectric permittivity and leakage current density of the capacitors according to the embodiment of FIG. 2 and the comparative examples of FIGS. 3A to 3C, respectively;

FIG. 6 is a cross-sectional view of a capacitor according to at least one embodiment;

FIG. 7 is fast Fourier transform (FFT) data illustrating the crystallinity of an electrode;

FIGS. 8 and 9 are graphs illustrating a dielectric permittivity and leakage current density of a capacitor, respectively;

FIG. 10 is a circuit diagram illustrating a schematic circuit according to some embodiments;

FIG. 11 is a diagram illustrating a semiconductor device according to at least one embodiment;

FIG. 12 is a diagram illustrating a semiconductor device according to at least one embodiment; and

FIGS. 13 and 14 are conceptual views schematically illustrating a device architecture applicable to a semiconductor device according to at least one embodiment.

### DETAILED DESCRIPTION

Reference will now be made in detail to embodiments, examples of which are illustrated in the accompanying drawings. Like reference numerals in the drawings denote like elements, and the size of each element in the drawings may be exaggerated for clarity and convenience of description. In this regard, the present embodiments may have different forms and should not be construed as being limited to the descriptions set forth herein. Accordingly, the embodiments are merely described below, by referring to the figures, to explain aspects. Meanwhile, embodiments described below are merely examples, and various modifications may be made from these embodiments. As used herein, the term “and/or” includes any and all combinations of one or more of the associated listed items. Expressions such as “at least one of,” when preceding a list of elements, modify the entire list of elements and do not modify the individual elements of the list.

Hereinafter, what is described as “above” or “on” may include those directly on, underneath, left, and right in contact, as well as above, below, left, and right in non-contact. The singular forms are intended to include the plural forms as well unless the context clearly indicates otherwise. Also, when a part “includes” any element, it means that the part may further include other elements, rather than excluding other elements, unless otherwise stated. Additionally, spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, device may be otherwise oriented, for example, rotated 90 degrees or at other orientations, and the spatially relative descriptors used herein should be interpreted accordingly.

The term “the” and the similar indicative terms may be used in both the singular and the plural. When there is no explicit description of the order of steps constituting a method or no contrary description thereto, these steps may be performed in an appropriate order, and are not limited to the order described.

Connections of lines or connection members between elements shown in the drawings are illustrative of functional connections and/or physical or circuitry connections, and may be replaced in an actual device, or may be represented as additional various functional connections, physical connections, or circuitry connections. In addition, as used herein, functional blocks, including those described with terms such “ . . . unit”, etc., denote units that are configured to perform at least one function or operation, which may be implemented as processing circuitry such as hardware, software, and/or a combination thereof. For example, the processing circuitry more specifically may include (and/or be included in), but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The use of all examples or example terms is merely for describing the technical concept in detail, and the scope thereof is not limited by these examples or example terms unless limited by claims. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

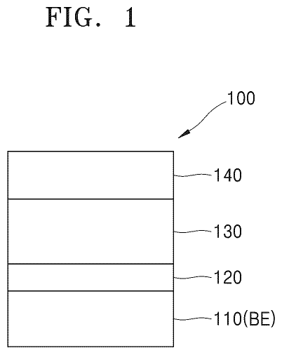

FIG. 1 is a cross-sectional view of a capacitor according to at least one embodiment.

Referring to FIG. 1, a capacitor 100 includes a first electrode BE including a conductive layer 110, a second electrode 140 spaced apart from the first electrode BE, a dielectric layer 130 disposed between the first electrode BE and the second electrode 140, and an interfacial layer 120 disposed between the first electrode BE and the dielectric layer 130.

The conductive layer 110 may include a first element, a second element, and a third element. The first element may include at least one of Ti or Al, the second element may include at least one of Ti, Al, Hf, Zr, Ta, Cr, Y, Sc, Si, Nb, Mo, V, W, Mn, Ni, or Co, and the third element may include N. The first element and the second element are different from each other. For example, when the first element is Ti, the second element is at least one of Al, Hf, Zr, Ta, Cr, Y, Sc, Si, Nb, Mo, V, W, Mn, Ni, or Co; and, when the first element is Al, the second element is Ti, Hf, Zr, Ta, Cr, Y, Sc, Si, Nb, Mo, V, W, Mn, Ni, or Co. Expressed differently, in at least one embodiment, the conductive layer 110 may include TiMiN, where M₁ may include at least one of Al, Hf, Zr, Ta, Cr, Y, Sc, Si, Nb, Mo, V, W, Mn, Ni, or Co. In addition, the conductive layer 110 may include M₂AlN, where M₂ may include at least one of Ti, Hf, Zr, Ta, Cr, Y, Sc, Si, Nb, Mo, V, W, Mn, Ni, or Co. The conductive layer 110 may include, for example, TiAlN. A thickness of the conductive layer 110 may be, for example, about 10 Å or more and about 100 Å or less. The thickness of the conductive layer 110 may be, for example, about 20 Å or more and about 50 Å or less. Therefore, in at least some embodiments, the thickness of the conductive layer 110 may be within a range of 10 Å to 100 and/or 20 Å to 50 Å.

The conductive layer 110 may have a rock salt crystal structure. The conductive layer 110 may be manufactured to have the rock salt crystal structure through reactive co-sputtering. The conductive layer 110 has the rock salt crystal structure, and thus, the capacitor 100 may have a low leakage current density and suppress a dielectric permittivity reduction.

For example, a TiAlN electrode having the rock salt crystal structure may be formed through reactive co-sputtering. The TiAlN electrode having the rock salt crystal structure may be formed by controlling a growth temperature, cation composition, and a substrate. Specifically, sputtering may be performed by using Ti and Al as target materials in a nitrogen atmosphere at a temperature of about 500° C. or higher. Also, a composition ratio of Al may be controlled to about 63 at % or less. In addition, the TiAlN electrode having the rock salt crystal structure may be formed by using an MgO substrate having the rock salt crystal structure and a lattice constant value of 4.2 Å similar to that of TiAlN in order to promote epitaxial growth and rock salt crystal structure propagation of the TiAlN.

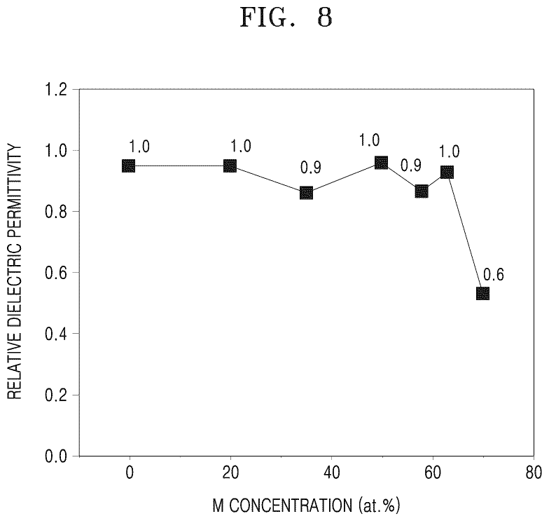

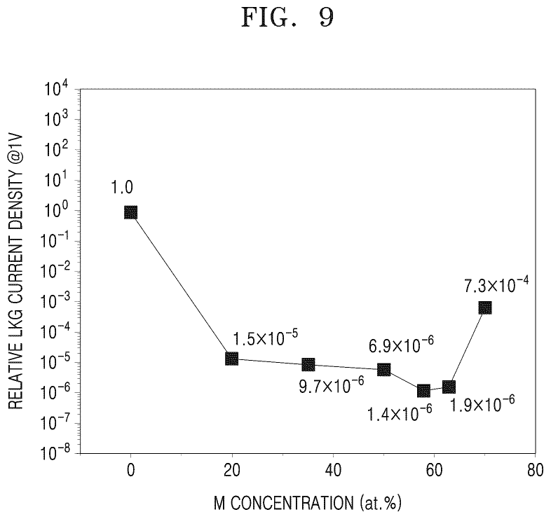

When the conductive layer 110 includes Al, the composition ratio of Al may be about 63 at % or less. The rock salt crystal structure may be maintained when the composition ratio of Al is about 63 at % or less. A detailed description in this regard is given below with reference to FIGS. 8 and 9.

The interfacial layer 120 may include an oxide of a material constituting the conductive layer 110. For example, when the conductive layer 110 is TiAlN, the interfacial layer 120 may be TiAlON. The interfacial layer 120 may be formed during crystallization of the dielectric layer 130 on the conductive layer 110. For example, when the conductive layer 110 is TiAlN, a TiAlON layer may be formed between the conductive layer 110 and the dielectric layer 130 during crystallization of the dielectric layer 130 on a TiAlN electrode. The thickness of the interfacial layer 120 may be, for example, about 5 Å or more and about 20 Å or less. The thickness of the interfacial layer 120 may be, for example, about 5 Å or more and about 10 Å or less. The capacitor 100 including the interfacial layer 120 may have a reduced leakage current density.

The dielectric layer 130 may include an oxide having a perovskite type crystal structure. The dielectric layer 130 may include at least one of Sr, Ba, Ti, Hf, and/or Y. The dielectric layer 130 may include, for example, BaSrTiO₃. However, the dielectric layer 130 is not limited thereto and may include a metal oxide. The dielectric layer 130 may include, for example, metal oxide including Ti, Hf, Zr, Y, Al, and/or Mg.

The dielectric layer 130 may have one or more structures selected from, for example, a flat plate structure, a trench structure, and a pillar structure, but the structures are not limited thereto. The dielectric layer 130 may have such a structure, and thus, may be applied to various types of devices. The dielectric layer 130 may have, for example, a single-layer structure or a multi-layer structure. The multi-layer structure may be a two-layer structure, a three-layer structure, a four-layer structure, etc., but is not necessarily limited to this range, and may have a multi-layer structure including more layers according to required performance.

The dielectric layer 130 may be an epitaxial layer. For example, the dielectric layer 130 may be formed by epitaxial growth. Accordingly, the dielectric layer 130 may have the same or similar crystal structure, the same or similar lattice constant, etc. as or to that of a thin film electrode layer 110, and may have an improved interfacial stability. The dielectric layer 130 may partly or wholly include an epitaxial region. For example, due to lattice mismatch, the dielectric layer 130 may have a region with higher lattice strain closer to the thin film electrode layer 110 and a region with lower lattice strain farther from the thin film electrode layer 110. Additionally, in at least some embodiments, the formation of the interfacial layer 120 may bond the dielectric layer 130 to the thin film electrode layer 110, such that the interfacial layer 120 also acts as an adhesive layer.

A thickness of the dielectric layer 130 may be, for example, about 10 Å or more and about 100 Å or less. The thickness of the dielectric layer 130 may be, for example, without a range of about 20 Å to about 50 Å. When the thickness of the dielectric layer 130 is too small, capacitance of the capacitor 100 per unit volume may decrease, and when the thickness of the dielectric layer 130 is too great, it may be difficult for the capacitor 100 to satisfy the volume required by a memory device.

The second electrode 140 may be disposed on the dielectric layer 130. The second electrode 140 may be a metal layer including Pt, Ir, Ru, Ti, or W. However, the second electrode 140 is not limited thereto, and may, in at least some embodiments, include the same material as that of the conductive layer 110.

FIG. 1 illustrates that the conductive layer 110 and the interfacial layer 120 are disposed on a lower portion of the dielectric layer 130, but the conductive layer 110 and the interfacial layer 120 may be disposed on an upper portion of the dielectric layer 130.

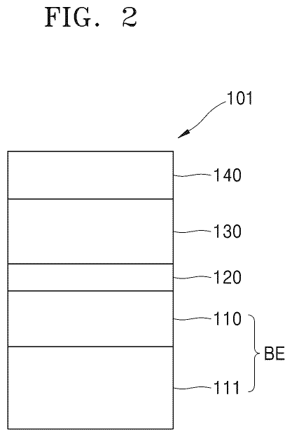

FIG. 2 is a cross-sectional view of a capacitor according to at least one embodiment.

Referring to FIG. 2, a capacitor 101 includes the first electrode BE including the conductive layer 110 and a second conductive layer 111 disposed on a lower portion of the conductive layer 110, the second electrode 140 spaced apart from the electrode BE, the dielectric layer 130 disposed between the first electrode BE and the second electrode 140, and the interfacial layer 120 disposed between the first electrode BE and the dielectric layer 130. In the following description, the conductive layer 110 may be referred to as a first conductive layer 110 to be distinguished from the second conductive layer 111.

The second conductive layer 111 may include TiN. The thickness of the second conductive layer 111 may be, for example, about 30 Å or more and about 500 Å or less. For example, a thickness of the second conductive layer 111 may be within a range of about 50 Å to about 300 Å.

In at least one example, the first conductive layer 110 may include TiAlN, the second conductive layer 111 may include TiN, the dielectric layer 130 may include BaSrTiO₃, the interfacial layer 120 may include TiAlON, and the second electrode 140 may include Pt.

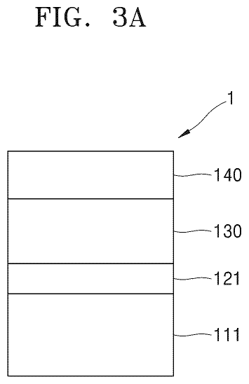

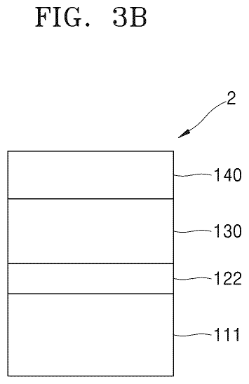

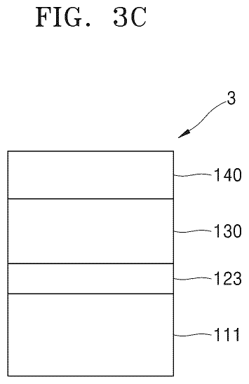

FIGS. 3A to 3C are cross-sectional views illustrating capacitors according to comparative examples.

Referring to FIG. 3A, a capacitor 1 of Comparative Example 1 includes the second conductive layer 111, the dielectric layer 130 spaced apart from the second conductive layer 111, an interfacial layer 121 disposed between the second conductive layer 111 and the dielectric layer 130, and the second electrode 140 disposed on the dielectric layer 130.

In Comparative Example 1, the second conductive layer 111 may include TiN, the dielectric layer 130 may include BaSrTiO₃, the interfacial layer 121 may include TiON, and the second electrode 140 may include Pt.

Comparative Example 1 is the same as capacitor 101 except that the interfacial layer 121 includes TiON.

Referring to FIG. 3B, a capacitor 2 of Comparative Example 2 includes the second conductive layer 111, the dielectric layer 130 spaced apart from the second conductive layer 111, an interfacial layer 122 disposed between the second conductive layer 111 and the dielectric layer 130, and the second electrode 140 disposed on the dielectric layer 130.

In Comparative Example 2, the second conductive layer 111 may include TiN, the dielectric layer 130 may include BaSrTiO₃, the interfacial layer 122 may include Al, and the second electrode 140 may include Pt.

Comparative Example 2 is the same as capacitor 101 except that the interfacial layer 122 includes Al.

Referring to FIG. 3C, a capacitor 3 of Comparative Example 3 includes the second conductive layer 111, the dielectric layer 130 spaced apart from the second conductive layer 111, an interfacial layer 123 disposed between the second conductive layer 111 and the dielectric layer 130, and the second electrode 140 disposed on the dielectric layer 130.

In Comparative Example 3, the second conductive layer 111 may include TiN, the dielectric layer 130 may include BaSrTiO₃, the interfacial layer 123 may include Al₂O₃, and the second electrode 140 may include Pt.

Comparative Example 3 is the same as capacitor 101 except that the interfacial layer 123 includes Al₂O₃.

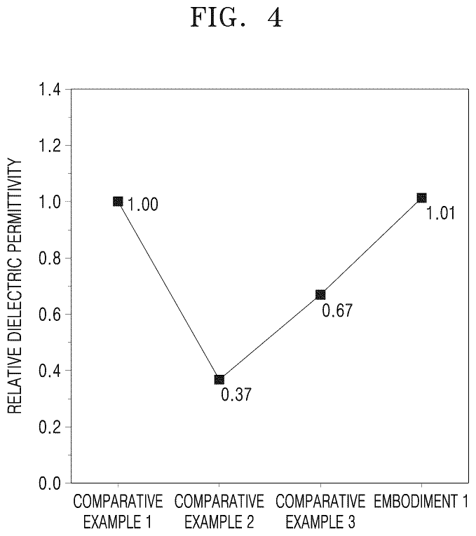

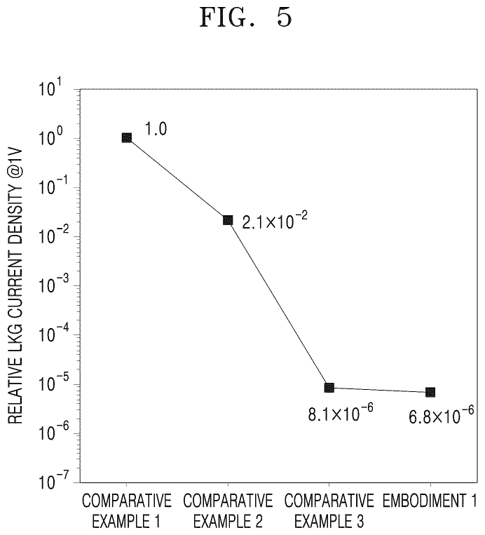

FIGS. 4 and 5 are graphs illustrating a dielectric permittivity and leakage current density of capacitors according to the embodiment of FIG. 2 and the comparative examples of FIGS. 3A to 3C, respectively.

Referring to FIG. 4, dielectric permittivity patterns of the capacitors according to a material change between a first electrode and an interfacial layer may be known. When the dielectric permittivity of the capacitor 1 of Comparative Example 1 is 1.00, the capacitor 2 of Comparative Example 2 has a relative dielectric permittivity of about 0.37, the capacitor 3 of Comparative Example 3 has a relative dielectric permittivity of about 0.67, and the capacitor 101 of Embodiment 1 has a relative dielectric permittivity of about 1.01.

As described above, the capacitor 101 of Embodiment 1, in which a perovskite dielectric layer is crystallized on a TiAlN electrode, is confirmed as having the highest dielectric permittivity.

Referring to FIG. 5, dielectric permittivity patterns of the capacitors according to a material change between a first electrode and an interfacial layer may be known. In a case where a voltage of ±1 V is applied to the capacitors, when the leakage current density of the capacitor 1 of Comparative Example 1 is 1.0, a relative leakage current density of the capacitor 2 of Comparative Example 2 is about 2.1×10⁻², a relative leakage current density of the capacitor 3 of Comparative Example 3 is about 8.1×10⁻⁶, and a relative leakage current density of the capacitor 101 of Embodiment 1 is about 6.8×10⁻⁶.

As described above, the lowest leakage current density is measured in the capacitor 101 according to Embodiment 1 in which the perovskite dielectric layer is crystallized on the TiAlN electrode. Therefore, it can be seen that the capacitor 101, compared to the comparative examples, has a low leakage current density and a high dielectric permittivity.

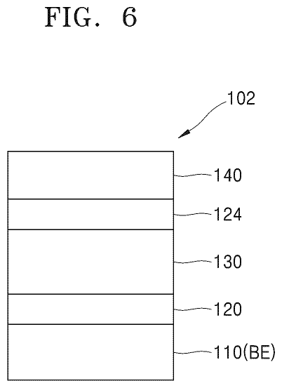

FIG. 6 is a cross-sectional view of a capacitor according to at least one embodiment.

Referring to FIG. 6, a capacitor 102 may include the first electrode BE including the conductive layer 110, the second electrode 140 spaced apart from the first electrode BE, the dielectric layer 130 disposed between the first electrode BE and the second electrode 140, and the interfacial layer 120 disposed between the first electrode BE and the dielectric layer 130. The conductive layer 110, the dielectric layer 130, and the interfacial layer 120 may be respectively the same as the conductive layer 110, the dielectric layer 130, and the interfacial layer 120 of the capacitor 100 of FIG. 1. A description redundant with that of FIG. 1 is omitted.

The second electrode 140 may include the same material as that of the conductive layer 110. For example, the second electrode 140 may include the first element, the second element, and the third element. The first element may include Ti or Al, the second element may include Ti, Al, Hf, Zr, Ta, Cr, Y, Sc, Si, Nb, Mo, V, W, Mn, Ni, or Co, and the third element may include N. The first element and the second element are different from each other. For example, when the first element is Ti, the second element may be Al, Hf, Zr, Ta, Cr, Y, Sc, Si, Nb, Mo, V, W, Mn, Ni, or Co. For example, when the first element is Al, the second element may be Ti, Hf, Zr, Ta, Cr, Y, Sc, Si, Nb, Mo, V, W, Mn, Ni, or Co. The second electrode 140 may include, for example, TiAlN. The thickness of the second electrode 140 may be, for example, about 10 Å or more and about 100 Å or less.

The second electrode 140 may also have a rock salt crystal structure. The second electrode 140 may be manufactured to have the rock salt crystal structure through reactive co-sputtering. The second electrode 140 has the rock salt crystal structure, and thus, the capacitor 102 may have a low leakage current density and suppress a dielectric permittivity reduction. When the second electrode 140 includes Al, a composition ratio of Al may be about 63 at % or less. The rock salt crystal structure may be maintained when the composition ratio of Al is about 63 at % or less.

The capacitor 102 may further include a second interfacial layer 124 disposed between the second electrode 140 and the dielectric layer 130. In these cases, the interfacial layer 120 may be referred to as a first interfacial layer 120 to be distinguished from the second interfacial layer 124. The second interfacial layer 124 may include oxide of a material constituting the second electrode 140. For example, when the second electrode 140 is TiAlN, the second interfacial layer 124 may be TiAlON.

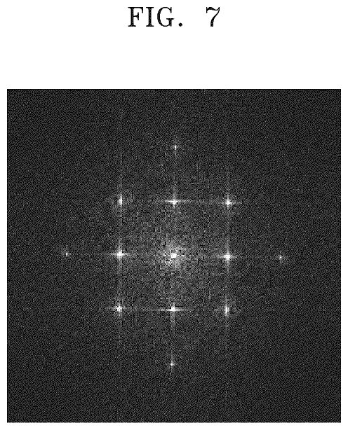

FIG. 7 is fast Fourier transform (FFT) data illustrating the crystallinity of an electrode.

Referring to the FFT data of FIG. 7, a first electrode including TiAlN exhibits a rock salt crystal structure. Accordingly, it may be confirmed that the first electrode including TiAlN has a single crystal or a high crystallinity close thereto obtained by an epitaxial growth.

FIGS. 8 and 9 are graphs illustrating a dielectric permittivity and a leakage current density of a capacitor, respectively.

Referring to FIG. 8, a dielectric permittivity pattern of the capacitor according to a composition ratio of a metal M of an electrode including TiMN may be known. The metal M may be, for example, aluminum. In a case where the composition ratio of the metal M is 0 at % and a dielectric permittivity of the capacitor is 1.0, when the composition ratio of the metal M is 20 at %, a relative dielectric permittivity of the capacitor is about 1.0, when the composition ratio of the metal M is 35 at %, the relative dielectric permittivity of the capacitor is about 0.9, when the composition ratio of the metal M is 50 at %, the relative dielectric permittivity of the capacitor is about 1.0, when the composition ratio of the metal M is 58 at %, the relative dielectric permittivity of the capacitor is about 0.9, when the composition ratio of the metal M is 63 at %, the relative dielectric permittivity of the capacitor is about 1.0, and when the composition ratio of the metal M is 70 at %, the relative dielectric permittivity of the capacitor is about 0.6. It may be confirmed that the dielectric permittivity of the capacitor is rapidly reduced when the composition ratio of the metal M exceeds 63 at %.

Referring to FIG. 9, a leakage current density pattern of the capacitor according to the composition ratio of the metal M of the electrode including TiMN may be known. The metal M may be, for example, aluminum. In a case where the composition ratio of the metal M is 0 at % and the leakage current density of the capacitor is 1.0, when the composition ratio of the metal M is 20 at %, the relative leakage current density of the capacitor is about 1.5×10⁻⁵, when the composition ratio of the metal M is 35 at %, the relative leakage current density of the capacitor is about 9.7×10⁻⁶, when the composition ratio of the metal M is 50 at %, the relative leakage current density of the capacitor is about 6.9×10⁻⁶, when the composition ratio of the metal M is 58 at %, the relative leakage current density of the capacitor is about 1.4×10⁻⁶, when the composition ratio of the metal M is 63 at %, the relative leakage current density of the capacitor is about 1.9×10⁻⁶, and when the composition ratio of the metal M is 70 at %, the relative leakage current density of the capacitor is about 7.3×10⁻⁴. It may be seen that the leakage current density is reduced when the electrode includes the metal M and increases rapidly when the composition ratio of the metal M exceeds 63 at %.

Through results of FIGS. 8 and 9, it may be seen that when the composition ratio of the metal M of the electrode including TiMN is 63 at % or less and more than 0 at %, the capacitor has a high dielectric permittivity and a low leakage current density, and the electrode including TiMN maintains a rock salt crystal structure.

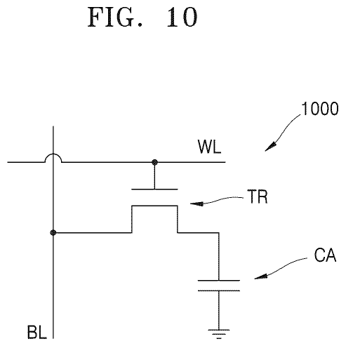

FIG. 10 is a circuit diagram illustrating a schematic circuit configuration according to some embodiments.

The circuit diagram of a semiconductor device 1000 relates to a single dynamic random access memory (DRAM) cell, and includes one transistor TR, one capacitor CA, a word line WL, and a bit line BL. The capacitor CA may be the capacitor 100, 101, or 102 described with reference to FIG. 1, 2, or 6 which has been described above, and thus, a description thereof is omitted.

A method of writing data to DRAM is as follows. A high gate voltage turning the transistor TR to an ‘ON’ state is applied to a gate electrode through the word line WL, and then, VDD (high) which is a data voltage value to be input or 0 (low), is applied to the bit line BL. When a high voltage is applied to the word line WL and the bit line BL, the capacitor CA is charged and data “1” is written. When a high voltage is applied to the word line WL and a low voltage is applied to the bit line BL, the capacitor CA is discharged and data “0” is written.

When data is read, a high voltage is applied to the word line WL to turn on the transistor TR of the DRAM, and then a voltage of VDD/2 is applied to the bit line BL. When the DRAM data is “1”, that is, when the voltage of the capacitor CA is VDD, charges in the capacitor CA move slowly to the bit line BL so that the voltage of the bit line BL is slightly higher than VDD/2. Conversely, when the data of the capacitor CA is “0”, the charges of the bit line BL move to the capacitor CA so that the voltage of the bit line BL is slightly lower than VDD/2. A sense amplifier may sense a potential difference of the bit line BL generated as above and amplify a potential difference value to determine whether the data is “0” or “1”.

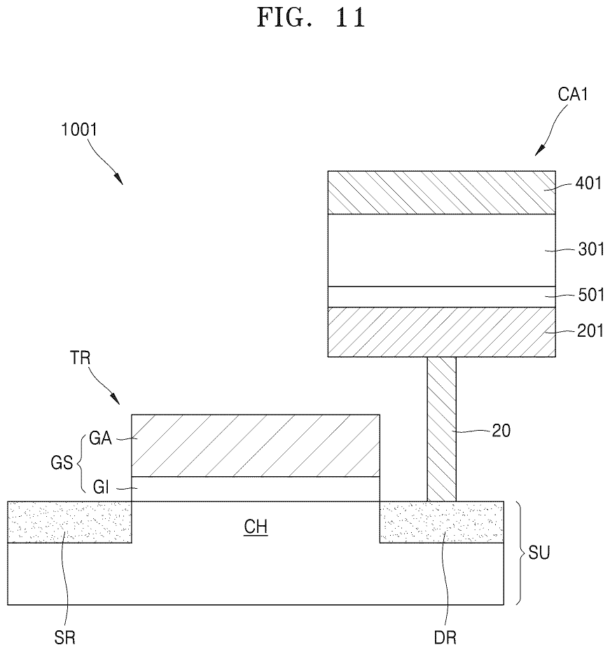

FIG. 11 is a diagram illustrating a semiconductor device according to at least one embodiment.

Referring to FIG. 11, in a semiconductor device 1001, a capacitor CA1 and the transistor TR may be electrically connected to each other through a contact 20. The capacitor CA1 includes a first electrode 201, a second electrode 401, a dielectric layer 301 disposed between the first electrode 201 and the second electrode 401, and an interfacial layer 501 disposed between the dielectric layer 301 and the second electrode 401. The capacitor CA1 may be the capacitor 100, 101, or 102 described with reference to FIG. 1, 2, or 6, which has been described above, and thus, a description thereof is omitted.

The transistor TR may be a field effect transistor. The transistor TR may include a semiconductor substrate SU including a source region SR, a drain region DR, and a channel region CH and a gate stack GS disposed on the semiconductor substrate SU to face a channel region CH and including a gate insulating layer GI and a gate electrode GA.

The channel region CH is a region between the source region SR and the drain region DR, and is electrically connected to the source region SR and the drain region DR. The source region SR may be electrically connected to or in contact with one end of the channel region CH, and the drain region DR may be electrically connected to or in contact with the other end of the channel region CH. The channel region CH may be defined as a substrate region between the source region SR and the drain region DR in the semiconductor substrate SU.

The semiconductor substrate SU may include a semiconductor material. The semiconductor substrate SU may include, for example, a semiconductor material such as silicon (Si), germanium (Ge), silicon germanium (SiGe), silicon carbide (SiC), gallium arsenide (GaAs), indium arsenide (InAs), indium phosphide (InP), and/or the like. Also, the semiconductor substrate SU may include a silicon on insulator (SOI) substrate.

The source region SR, the drain region DR, and the channel region CH may be independently formed by injecting impurities into different regions of the semiconductor substrate SU. In these cases, the source region SR, the channel region CH, and the drain region DR may each include a substrate material as a base material. The source region SR and the drain region DR may include a conductive material. In this case, the source region SR and the drain region DR may include, for example, a metal, a metal compound, or conductive polymer.

In at least some embodiments, unlike what is illustrated, the channel region CH may be implemented as a separate material layer (thin film). In this case, the channel region CH may include, for example, one or more of Si, Ge, SiGe, a Group III-V semiconductor, an oxide semiconductor, a nitride semiconductor, an oxynitride semiconductor, a two-dimensional (2D) material, a quantum dot, and an organic semiconductor. The oxide semiconductor may include, for example, InGaZnO. The 2D material may include, for example, transition metal dichalcogenide (TMD) or graphene. The QD may include, for example, a colloidal QD or a nanocrystal structure.

The gate electrode GA may be disposed on the semiconductor substrate SU to be spaced apart from the semiconductor substrate SU and face the channel region CH. The gate electrode GA may include at least one of metal, metal nitride, metal carbide, or polysilicon. The metal may include, for example, at least one of aluminum (Al), tungsten (W), molybdenum (Mo), titanium (Ti), or tantalum (Ta). The metal nitride film may include, for example, one or more of a titanium nitride (TiN) film and a tantalum nitride (TaN) film. The metal carbide may include, for example, one or more of the metal carbides doped (or containing) aluminum and silicon. The metal carbide may include, for example, TiAlC, TaAlC, TiSiC, or TaSiC.

The gate electrode GA may have a structure in which a plurality of materials are stacked. The gate electrode GA may have, for example, a stack structure of a metal nitride layer/metal layer such as TiN/Al or a stack structure of a metal nitride layer/metal carbide layer/metal layer such as TiN/TiAlC/W. The materials mentioned above used for the gate electrode GA are merely examples and are not limited thereto.

The gate insulating layer GI may be further disposed between the semiconductor substrate SU and the gate electrode GA. The gate insulating layer GI may include a paraelectric material or a high-k dielectric material. The gate insulating layer GI may have, for example, a dielectric permittivity of about 20 to about 70.

The gate insulating layer GI may include an insulative material, for example, silicon oxide, silicon nitride, aluminum oxide, hafnium oxide, zirconium oxide, or a 2D insulator such as hexagonal boron nitride (h-BN). The gate insulating layer GI may include, for example, silicon oxide (SiO₂), silicon nitride (SiNₓ), etc., and may include hafnium oxide (HfO₂), hafnium silicon oxide (HfSiO₄), lanthanum oxide (La₂O₃), lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc0.5Ta0.5O3), lead zinc niobate (PbZnNbO3), etc. The gate insulating layer GI may include, for example, metal nitride oxide such as aluminum oxynitride (AlON), zirconium oxynitride (ZrON), hafnium oxynitride (HfON), lanthanum oxynitride (LaON), yttrium oxynitride (YON), etc., silicate such as ZrSiON, HfSiON, YSiON, LaSiON, etc., and/or aluminate such as ZrAlON, HfAlON, etc. The gate insulating layer GI may include, for example, a dielectric layer of the capacitor CA1 described above. The gate insulating layer GI may constitute a gate stack together with the gate electrode GA.

One of the electrodes 201 and 401 of the capacitor CA1 may be electrically connected to one of the source region SR and drain region DR of the transistor TR by the contact 20. The contact 20 may include a suitable conductive material, such as tungsten, copper, aluminum, polysilicon, etc.

The arrangement of the capacitor CA1 and the transistor TR may be modified in various ways. For example, the capacitor CA1 may have a structure disposed on the semiconductor substrate SU or a structure buried in the semiconductor substrate SU.

FIG. 11 illustrates the semiconductor device 1001 including one capacitor CA1 and one transistor TR, but this is an example, and the semiconductor device 1001 may include a plurality of capacitors and a plurality of transistors.

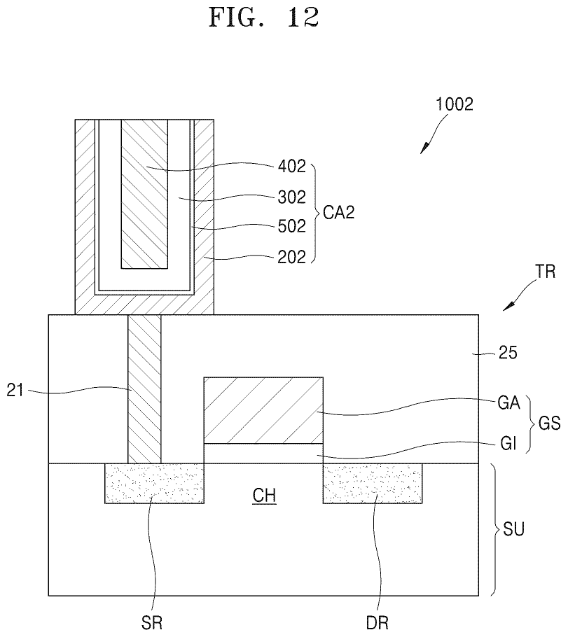

FIG. 12 is a diagram illustrating a semiconductor device according to at least one embodiment.

Referring to FIG. 12, a semiconductor device 1002 may include a capacitor CA2 and the transistor TR. The semiconductor device 1002 may include a structure in which the capacitor CA2 and the transistor TR are electrically connected to each other by a contact 21.

The transistor TR includes the semiconductor substrate SU including the source region SR, the drain region DR, and the channel region CH positioned between the source region SR and the drain region DR, and the gate stack GS disposed on the semiconductor substrate SU to face the channel region CH and including the gate insulating layer GI and the gate electrode GA.

An interlayer insulating layer 25 may be provided on the semiconductor substrate SU to cover the gate stack GS. The interlayer insulating layer 25 may include an insulating material. The interlayer insulating layer 25 may include, for example, Si oxide (e.g., SiO₂), Al oxide (e.g., Al₂O₃), or a high dielectric material (e.g., HfO₂). The contact 21 passes through the interlayer insulating layer 25 and electrically connects the transistor TR to the capacitor CA2.

The capacitor CA2 includes a first electrode 202, a second electrode 402, a dielectric layer 302 disposed between the first electrode 202 and the second electrode 402, and an interfacial layer 502 disposed between the dielectric layer 302 and the second electrode 402. The first electrode 202 and the second electrode 402 are presented in a shape that may increase a contact area with the dielectric layer 302, and a material of the capacitor CA2 may be substantially the same as that of the capacitor 100, 101, or 102 described with reference shown in FIG. 1, 2, or 6.

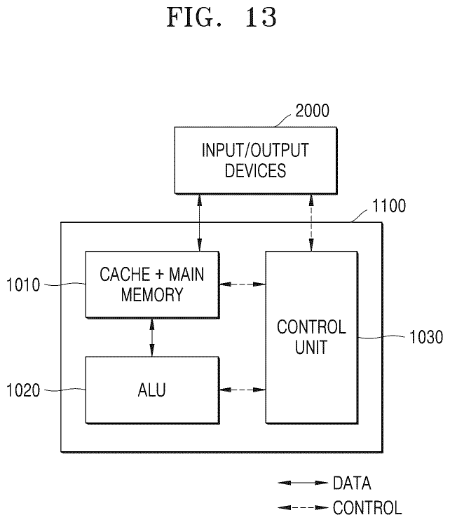

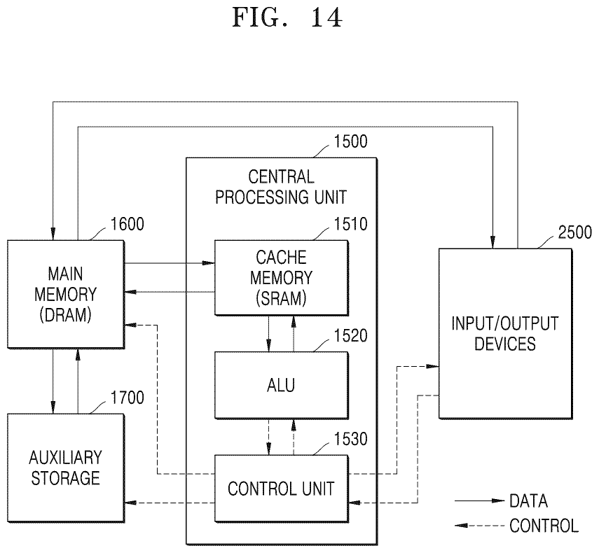

FIGS. 13 and 14 are conceptual views schematically illustrating a device architecture applicable to a semiconductor device according to at least one embodiment. For example, in at least some embodiments, the second electrode 402 may be presented in a pillar or cylinder shape.

Referring to FIG. 13, a semiconductor device architecture 1100 may include a memory unit 1010, an arithmetic logic unit (ALU) 1020, and a control unit 1030. The memory unit 1010, the ALU 1020, and the control unit 1030 may be electrically connected to each other. The electronic device architecture 1100 may be implemented as a single chip including, for example, the memory unit 1010, the ALU 1020, and the control unit 1030.

The memory unit 1010, the ALU 1020, and the control unit 1030 may be connected to each other through a metal line on-chip and communicate directly. The memory unit 1010, the ALU 1020, and the control unit 1030 may be monolithically integrated on one substrate to form the single chip. Input/output devices 2000 may be connected to the electronic device architecture (chip) 1100. The memory unit 1010 may include both main memory and cache memory. The electronic device architecture (chip) 1000 may be an on-chip memory processing unit. The memory unit 1010 may include the capacitor 100, 101, or 102 mentioned above and a semiconductor device using the capacitor 100, 101, or 102. The ALU 1020 or the control unit 1030 may also each include the capacitor mentioned above.

Referring to FIG. 14, a cache memory 1510, an ALU 1520, and a control unit 1530 may constitute a central processing unit (CPU) 1500, and the cache memory 1510 may include static random access memory (SRAM). Separately from the CPU 1500, a main memory 1600 and an auxiliary storage 1700 may be provided, and input/output devices 2500 may be provided. The main memory 1600 may be, for example, DRAM and may include the capacitor 100, 101, or 102 described with reference to FIG. 1, 2, or 6. For example, in at least one embodiment, the cache memory unit 1510, auxiliary memory 1700, and/or the main memory 1600, may include a plurality of the semiconductor device arranged in an array and configured to store data using a plurality of the capacitor 100, 101, or 102.

The input/output device (and/or devices) 2000 and 2500 may include, for example, an input device (such as a microphone, touch pad, electronic mouse, keyboard, keypad, camera, etc.) and/or an output device (such as a speaker, display, haptic system, etc.). According to at least some example embodiments, the input/output devices 2000 may be provided individually and/or in combination (e.g., a touch screen display).

In some cases, an electronic device architecture may be implemented in a form in which computing unit devices and memory unit devices are adjacent to each other in one chip without distinction of sub-units.

The capacitor and the semiconductor device including the same according to the present disclosure may include an interfacial layer including oxide of an electrode material on an electrode having a rock salt crystal structure, thereby having a low leakage current density and suppressing a dielectric permittivity reduction. While the capacitor and the semiconductor device including the same have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included.

According to the disclosed embodiments, the capacitor may crystallize a dielectric layer on a first electrode having a rock salt crystal structure, thereby having a low leakage current density and suppressing a dielectric permittivity reduction.

According to the disclosed embodiments, the semiconductor device including the capacitor may easily implement a high degree of integration and contribute to miniaturization of an electronic device.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode comprising a conductive layer;
a second electrode spaced apart from the first electrode;
a dielectric layer electrically separating the first electrode and the second electrode; and
an interfacial layer between the first electrode and the dielectric layer,
wherein the conductive layer comprises a material including a first element, a second element, and a third element,
the first element comprises Ti or Al,
the second element comprises at least one of Ti, Al, Hf, Zr, Ta, Cr, Y, Sc, Si, Nb, Mo, V, W, Mn, Ni, or Co,
the third element comprises N, and
the first element and the second element are different from each other, and
the conductive layer has a rock salt crystal structure.

2. The capacitor of claim 1, wherein
the conductive layer includes Al, and
a composition ratio of the Al is 63 at % or less.

3. The capacitor of claim 1, wherein the interfacial layer includes an oxide of the material included in the conductive layer.

4. The capacitor of claim 1, wherein the dielectric layer includes an oxide having a perovskite-type crystal structure.

5. The capacitor of claim 4, wherein the dielectric layer includes at least one of Sr, Ba, Ti, Hf, Y or O.

6. The capacitor of claim 1, wherein a thickness of the conductive layer is within a range of about 10 Å to about 100 Å.

7. The capacitor of claim 1, wherein a thickness of the interfacial layer is within a range of 5 Å to about 20 Å.

8. The capacitor of claim 1, wherein a thickness of the dielectric layer is within a range of 10 Å to about 100 Å.

9. The capacitor of claim 1, wherein
the conductive layer is a first conductive layer, and
the first electrode further includes a second conductive layer including TiN.

10. The capacitor of claim 9, wherein a thickness of the second conductive layer is within a range of about 30 to about 500.

11. The capacitor of claim 1, wherein the second electrode includes a same material as the material included in the conductive layer.

12. The capacitor of claim 1, further comprising:
a second interfacial layer between the second electrode and the dielectric layer.

13. The capacitor of claim 12, wherein the second interfacial layer includes an oxide of a material constituting the second electrode.

14. A semiconductor device comprising:
a transistor comprising a substrate comprising a source region, a drain region, and a channel region between the source region and the drain region and a gate stack over the channel region; and
a capacitor electrically connected to the transistor,
wherein the capacitor comprises
a first electrode comprising a conductive layer,
a second electrode spaced apart from the first electrode,
a dielectric layer electrically separating the first electrode and the second electrode, and
an interfacial layer between the first electrode and the dielectric layer,
the conductive layer comprises a material including a first element, a second element, and a third element,
the first element comprises Ti or Al,
the second element comprises at least one of Ti, Al, Hf, Zr, Ta, Cr, Y, Sc, Si, Nb, Mo, V, W, Mn, Ni, or Co,
the third element comprises N, and
the first element and the second element are different from each other, and
the conductive layer has a rock salt crystal structure.

15. The semiconductor device of claim 14, wherein
the conductive layer includes Al, and
a composition ratio of the Al is 63 at % or less.

16. The semiconductor device of claim 14, wherein the interfacial layer includes an oxide of the material included in the conductive layer.

17. The semiconductor device of claim 14, wherein the dielectric layer includes an oxide having a perovskite-type crystal structure.

18. The semiconductor device of claim 17, wherein the dielectric layer includes at least one of Sr, Ba, Ti, Hf, Y or O.

19. The semiconductor device of claim 14, wherein
the conductive layer is a first conductive layer, and
the first electrode further includes a second conductive layer including TiN.

20. The semiconductor device of claim 14, wherein the second electrode includes a same material as the material included in the conductive layer.
